(19) United States
(12) Patent Application Publication
(10) Pub. No.: US 2004/0135595 A1
(43) Pub. Date: Jul. 15, 2004

(54) Methods, systems, and devices for burn-in testing of optoelectronic devices

(75) Inventors: Fang-Zhong Chen, Fremont, CA (US); Wei Cai, Arcadia, CA (US); John Chen, Rowland Heights, CA (US); Chun Lei, Arcadia, CA (US); Robert Shih, Arcadia, CA (US)

Correspondence Address: WORKMAN NYDEGGER (F/K/A WORKMAN NYDEGGER & SEELEY), 60 EAST SOUTH TEMPLE, 1000 EAGLE GATE TOWER, SALT LAKE CITY, UT, 84111, US

(73) Assignee: Finisar Corporation

(21) Appl. No.: 10/696,759

(22) Filed: Oct. 29, 2003

Related U.S. Application Data
(60) Provisional application No. 60/422,805, filed on Oct. 30, 2002.

(51) Int. Cl. G01R 31/26; G01R 31/02

(52) U.S. Cl. 324/767; 324/760

(57) ABSTRACT

System and methods for life testing laser diodes is disclosed. The system includes a burn-in rack having a plurality of optoelectronic devices mounted within respective holders and electrical signal connectors that electrically couple the optoelectronic devices to a first electrical connector. A test apparatus holds the burn-in rack and has optical detectors arranged to receive electromagnetic radiation from the mounted optoelectronic devices and couple the output signals from the optical detectors to a second electrical connector. A computer electrically communicates with the connectors and generates a drive current deliverable to each optoelectronic device and receives data from the optical detectors that is based upon the output from each optoelectronic device. The measured optical power output from each optoelectronic device is stored at the computer and following analysis the optoelectronic devices are either removed from the rack or subjected to additional burn-in processes.

### CROSS-REFERENCE TO RELATED APPLICATIONS

This application claims priority to and the benefit of U.S. Provisional Patent Application Serial No. 60/422,805, filed Oct. 30, 2002, and entitled “Laser Burn-in Testing”, the disclosure of which is incorporated herein by this reference.

### BACKGROUND OF THE INVENTION

1. The Field of the Invention

The present invention relates generally to testing of laser diodes. More specifically, the present invention generally relates to testing a large number of laser diodes simultaneously during a burn-in process.

2. The Relevant Technology

Burn-in procedures are commonly utilized in production of optical components, such as laser diodes. Due to inconsistencies in manufacturing techniques and materials, optical components can have actual life cycles that differ significantly from design or theoretical life cycles. Industry norm is to operate optical components for an extended period at the manufacturing facility with the hope that those optical components having a less than desired life cycle fail during initial operation. These failed optical components, therefore, never exit from the manufacturing facility to interrupt data flowing in an optical network.

In the case of a laser diode manufacture, burn-in of laser diodes includes operating the laser diodes at elevated ambient temperatures for an extended period. Operating laser diodes at these elevated temperatures for a long period screens out those laser diodes having a tendency to fail prematurely. The burn-in process also includes periodical life testing of individual laser diodes. The life testing allows a manufacturer to track the operation of the laser diodes over a period to generate life characteristics of the laser diode and lists of failure modes. Conventionally, life testing of laser diodes involves periodically testing the laser diodes at room temperature. For example, during a burn-in process the laser diodes can operate at elevated temperatures for 1000 hours, while being removed every 50-100 hours to test individual lasers as part of life testing.

Unfortunately, a drawback of conventional life testing is that it is labor intensive. An individual manually removes a laser diode from the burn-in apparatus, mounts the laser diode for life testing at room temperature, and subsequently mounts the tested laser diode back in the burn-in apparatus following life testing. Significant costs are incurred through current burn-in and life testing procedures.

In light of the above, what is desired is an improved apparatus and method for performing burn-in and life testing of laser diodes that eliminates the drawbacks associated with moving laser diodes during the burn-in and life testing processes.

### BRIEF SUMMARY OF THE INVENTION

The present invention generally relates to methods and devices for testing optoelectronic devices, such as, but not limited to, laser diodes. The methods and systems of the present invention provide for testing multiple laser diodes without the need to manually remove individual laser diodes for life testing. By so doing, the present invention overcomes the problems discussed above.

In one exemplary configuration, the system includes a burn-in rack that cooperates with a testing apparatus. The burn-in rack includes a rack base that supports one or more optoelectronic device supports. Mounted to these supports are optoelectronic device holders that receive a plurality of optoelectronic devices. Disposed between the rack base and the optoelectronic device holders is a circuit board; the circuit board being electrically coupled to the optoelectronic devices when the same are disposed within the respective holders.

The test apparatus of one exemplary embodiment includes a support structure that receives the burn-in rack and aids with aligning the plurality of optoelectronic devices with one or more detectors of a detector assembly. Aligning the detectors with the optoelectronic devices allows the detectors to identifying different characteristics of the optoelectronic devices by sensing the output electromagnetic radiation or waves generated by the optoelectronic devices. The detectors, therefore, aid with characterizing each optoelectronic device and calibrating each optoelectronic device.

Both the test apparatus and the burn-in rack include electrical connectors to facilitate electrically communication with a computer. This computer controls the life-testing processes by generating a drive current deliverable to each optoelectronic device and receiving data from the optical detectors that is based upon the output from each optoelectronic device. The computer can store the measured optical power output from each optoelectronic device and display such information to a user. This allows the user, or the computer when the computer is performing functions automatically, to determine whether an optoelectronic device is to removed from the rack or subjected to additional burn-in processes.

The present invention also provides for methods for testing optoelectronic devices, such as laser diodes. The method includes a step for mounting a burn-in rack having a plurality of optoelectronic devices to a test apparatus having an array of optical detectors. Following mounting of the burn-in rack, the method can include a step for providing a drive current to each of the plurality of optoelectronic devices. This can occur as a computer generates the drive current to be delivered to the optoelectronic devices. As each optoelectronic device generates electromagnetic radiation or waves, the method includes a step for measuring the optical power output of each optoelectronic device using the optical detectors. The data generated from the optical detectors can be stored at the computer for use in calibrating the optoelectronic devices.

The exemplary method of the present invention can also include a step for characterizing each optoelectronic device based upon a monitor detector integrated with each optoelectronic device. The characterizing step can include identifying (i) particular output power level for an input drive current, (ii) spectral characteristics of the output electromagnetic radiation or wave, (iii) spatial characteristics of the output electromagnetic radiation or wave, or (iv) other desirable characteristics of the output electromagnetic radiation or wave. Following characterizing each optoelectronic device, the method can include a step for calibrating the integrated detector and/or the optical detectors associated with the detector assembly.

Based upon the characterizing and/or calibrating steps, the method can include steps for removing the burn-in rack and performing a burn-in process, removing individual optoelectronic device that meet the desired criterion, re-characterizing each optoelectronic device and subsequently removing each of the plurality of optoelectronic devices following an additional burn-in process.

These and other objects and features of the present invention will become more fully apparent from the following description and appended claims, or may be learned by the practice of the invention as set forth hereinafter.

### BRIEF DESCRIPTION OF THE DRAWINGS

To clarify further the above and other advantages and features of the present invention, a more particular description of the invention will be rendered by reference to specific embodiments thereof that are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 is a perspective view of a burn-in system according to one embodiment of the present invention;

FIG. 2 is a perspective view of a burn-in rack having a burn-in board for holding laser diodes according to one embodiment of the present invention;

FIG. 3 is a cross-sectional view of a portion of the burn-in rack of FIG. 2 according to one embodiment of the present invention;

FIG. 4 is a plan view of a burn-in rack having a burn-in board for holding laser diodes according to one embodiment of the present invention;

FIG. 5 is a perspective view of a detector assembly having a detector array according to one embodiment of the present invention;

FIG. 6 is an exemplary flow diagram of one method of life testing using the burn-in system of FIG. 1 according to one embodiment of the present invention;

FIG. 7 is an exemplary flow diagram illustrating another method of life testing using the burn-in system of FIG. 1 according to one embodiment of the present invention.

### DETAILED DESCRIPTION OF THE EXEMPLARY EMBODIMENTS

The present invention generally relates to methods, systems, and devices for improving the manner by which burn-in and life testing occur during manufacturing processes. Through use of the present invention, a decrease of inefficient handling of individual optical components, such as laser diodes, takes place. Consequently, the methods, systems, and devices of the present invention decrease costs and time required to perform life testing during optical component manufacture.

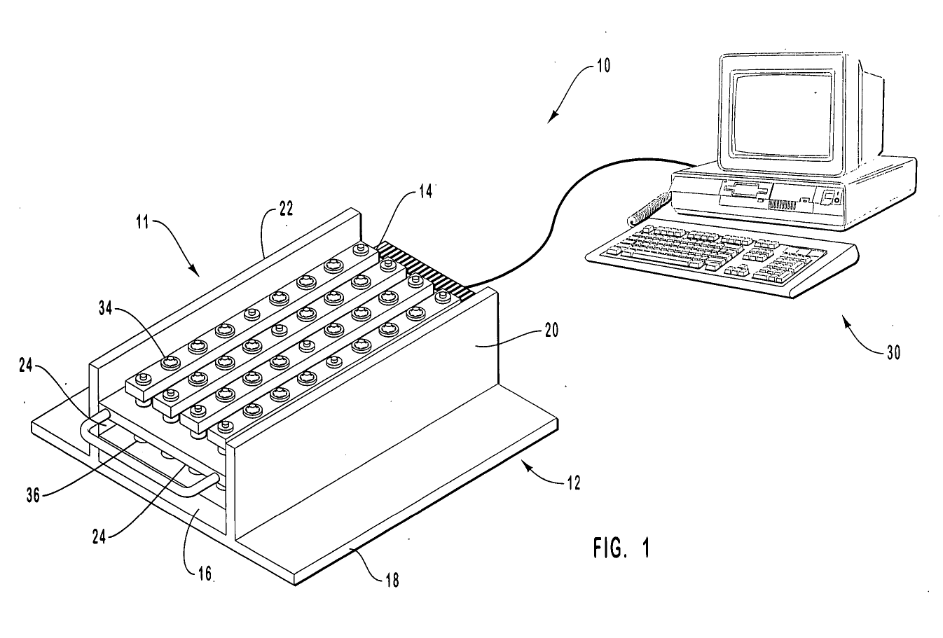

Referring to FIG. 1, illustrated is a system according to one configuration of the present invention; the system identified by reference numeral 10. The system 10 is usable for testing optical components during burn-in and life testing. The system 10, in the exemplary configuration, can test a plurality of laser diodes without the need to manually remove individual laser diodes to perform life testing during the burn-in process.

As illustrated, system 10 includes a testing apparatus 11 having a support structure 12 that receives a burn-in rack 14 and a detector assembly 16. The support structure 12 includes a base 18 upon which mount a first support member 20 and a second support member 22. Disposed from first support member 20 a sufficient distance to enable burn-in rack 14 and detector assembly 16 to position therebetween is second support member 22. Rack support 24 mounted to first support member 20 and second support member 22 hold burn-in rack 14, while base 16 supports detector assembly 16. One skilled in the art will understand that an additional rack support can support detector assembly 16; this additional rack support being linked to base 14, first support member 20, and/or second support member 22.

Various configurations of support structure 12 are possible, so long as they support one or more burn-in racks and one or more detector assemblies. In one configuration, each support member includes an integral rack support that holds one or more burn-in racks. In another configuration, each support member includes a groove or channel that acts as a rack support; the burn-in rack and/or detector assembly slidably received within the groove or channel. In another configuration, multiple support members hold or receive multiple racks or assemblies.

Linked to burn-in rack 14 and detector assembly 16 is computer 30 or other hardware device. The computer 30 can be a special purpose or general-purpose computer including various computer hardware, such as, but not limited to, such hardware associated with personal computers, hand-held devices, multi-processor systems, microprocessor-based or programmable consumer electronics, network PCs, minicomputers, mainframe computers, and the like. The computer 30 can form part of a distributed computing environment where tasks are performed by local and remote processing devices that are linked (either by hardwired links, wireless links, or by a combination of hardwired or wireless links) through a communications network.

The computer 30 can include computer-readable media for carrying or having computer-executable instructions or data structures stored thereon that facilitate control of the burn-in testing and life testing. These data structures can also represent optical characteristics of each laser diode, such as power output based upon input driving current, spectral characteristics of electromagnetic radiation output from tested optoelectronic devices, spatial characteristics of electromagnetic radiation output from tested optoelectronic devices, or other data representing the performance of each tested optoelectronic device.

The computer-readable media can be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, flash memory, or any other medium that can be used to carry or store desired program code means in the form of computer-executable instructions or data structures and that can be accessed by a general purpose or special purpose computer, such as computer 30. When information is transferred or provided over a network or another communications connection (either hardwired, wireless, or a combination of hardwired or wireless) to computer 30 or some other hardware device, computer 30 or the hardware device properly views the connection as a computer-readable medium. Thus, any such connection is properly termed a computer-readable medium. Combinations of the above should also be included within the scope of computer-readable media. Computer-executable instructions include, for example, instructions and data that cause a general purpose computer, special purpose computer, or special purpose processing device to perform a certain function or group of functions.

Generally, computer 30 controls the burn-in and life testing of a plurality of laser diodes 34 supported by burn-in rack 14. Software and/or hardware components and modules (not shown but understood by one skilled in the art) of computer 30 control the (i) operating time of laser diodes 34 supported by burn-in rack 14, (ii) time when life testing of individual laser diodes 34 occurs, (iii) operating procedures of one or more detectors 36 of detector assembly 16, (iv) detecting of the output from laser diodes 34 and/or internal monitor photo-diodes of the packaged laser diode, when applicable, and (v) storing the characterization data for each laser diode 34. Computer 30, for example, can include associated signal drivers and detectors appropriate for laser diodes 34 and detectors 36. Additionally, computer 30 can control the testing of each laser diode 34, such as by performing an L-I (light power versus current) analysis using detectors 36 to detect light power resulting from the delivery of a defined drive current to laser diodes 34. Such L-I analysis can occur in a sequential or non-sequential manner during the life testing.

To enable a user to view the results of the burn-in testing and/or life testing, computer 30 can include a computer display, such as a video display, liquid crystal display, or some other display that visually depicts the results of testing. Additionally, computer 30 can include virtual, volatile, and/or non-volatile memory for storing the test results.

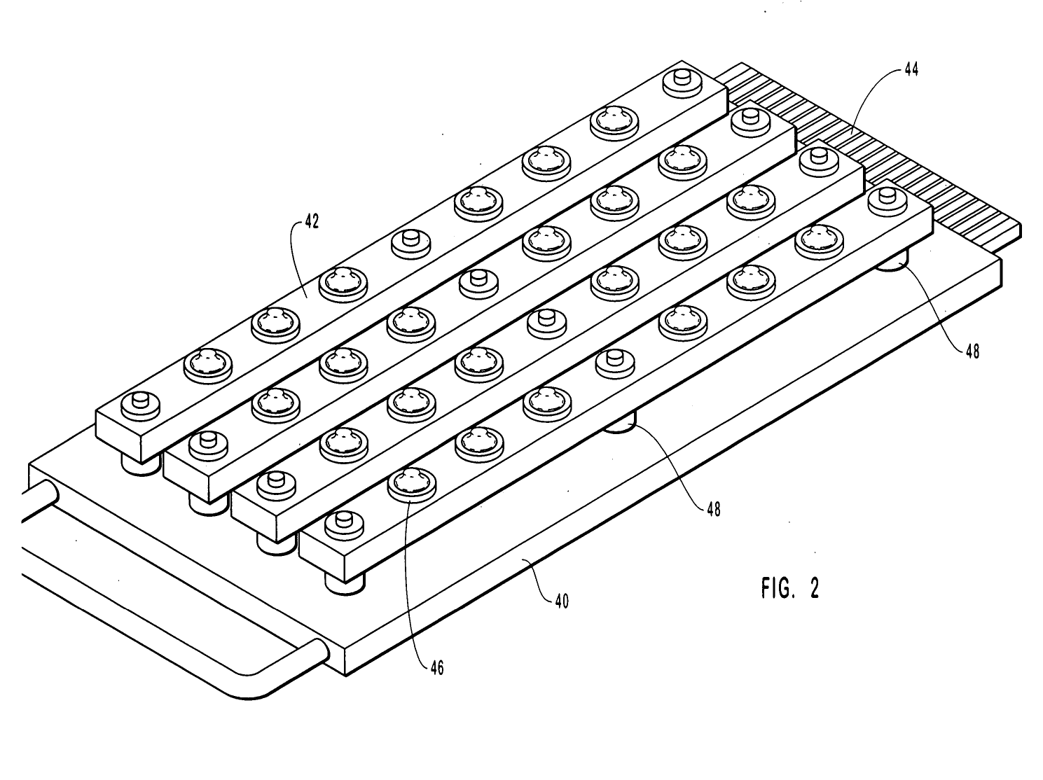

Efficiently performing the burn-in and life testing occurs through use of burn-in rack 14 and detector assembly 16. The burn-in rack 14, as shown in FIG. 2, includes rack base 40 that supports one or more diode supports 42 and a circuit board 44. Rack base 40 includes a handle 48 that aids with positioning burn-in rack 14 within support structure 12 (FIG. 1). Various configurations of handle 48 and/or rack base 40 can be used to enable a user to position burn-in rack 14. For instance, rack base 40 can include an integral or removable handle or other structure that a user grasps to position burn-in rack 14.

Diode support 42 each includes one or more diode holders 46 that receive laser diodes, such as laser diodes usable in TO packages. As shown in FIG. 2, holders 46 position laser diodes 34 relative to circuit board 44 so that electrical connection occurs between laser diodes 34 and circuit board 44 and hence computer 30 (FIG. 1) connected to circuit board 44. These holders 46 can be arranged as an array or other efficient arrangement for placing laser diodes 34 on burn-in rack 14. One or more holders 46 can be disposed on a single diode support 42. Consequently, a burn-in rack 14 can include one or a plurality of holders that received laser diodes. This is an advance over exiting technologies that are incapable of receiving multiple diodes and performing burn-in and life testing of many laser diodes at one time.

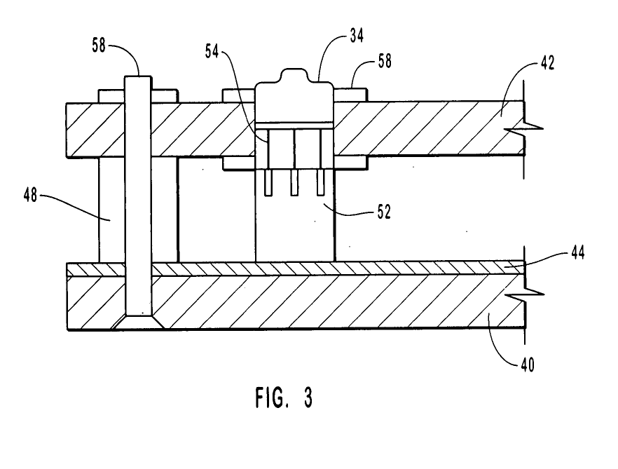

Each holder 46 can include a bushing within which mounts laser diode 34. The bushing maintains laser diode 34 in the desired orientation relative to circuit board 44 and electrical connector 52 shown in FIG. 3. This enables electrical pins 54 to mate with electrical connector 52 and so make electrical connection with circuit board 44. By so doing, computer 30 (FIG. 1) controls the operation of laser diode 34 as electrical signals pass from computer 30 (FIG. 1), to circuit board 44, electrical connector 52, and pins 54.

With continued reference to FIG. 3, spacer members 48 separate diode support 42 from circuit board 44 in the desired relative relationship. These spacer members 48 have a generally cylindrical configuration and are fastened to rack base 40 and diode supports 42 through fastener 58. Fastening of spacer members 48 occurs through a releasable or fixed fastener, adhesives, slip-fit or friction fit configuration, complementary engaging structures, such as threads, or other manners by which one member attached to another member.

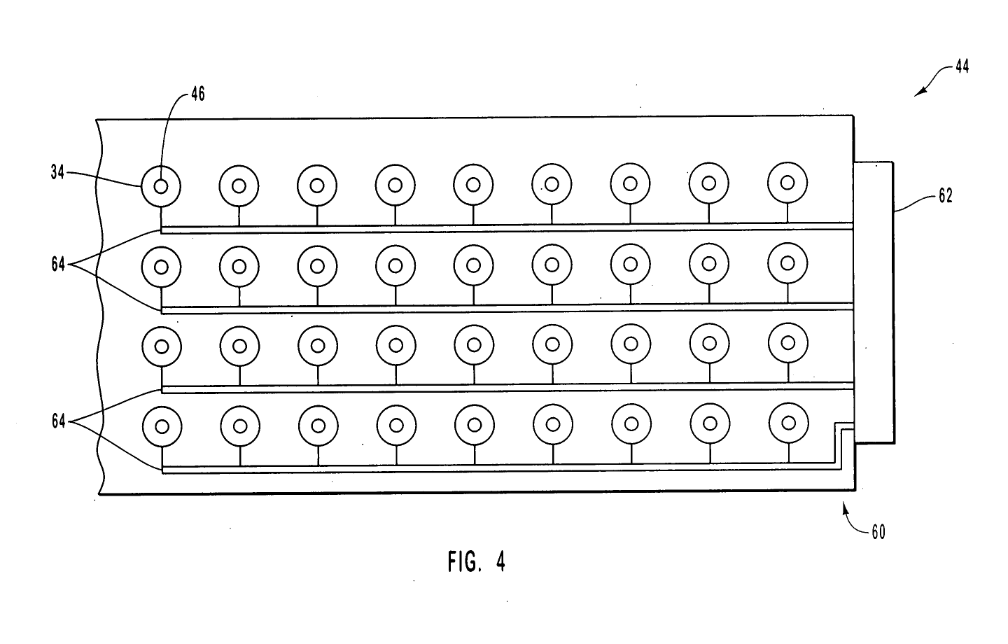

Mounted to rack base 40 is circuit board 44. As shown in FIG. 4, an end 60 of circuit board 44 is formed with or as an electrical connector 62, such as an edge connector, which enables transport of electrical signals to and from computer 30 (FIG. 1). This connector 62 electrically cooperates with one or more traces 64, as shown schematically in FIG. 4, which each act as a signal bus to permit electrical signals from computer 30 to be coupled to laser diodes 34 when the same are disposed within a holder 46.

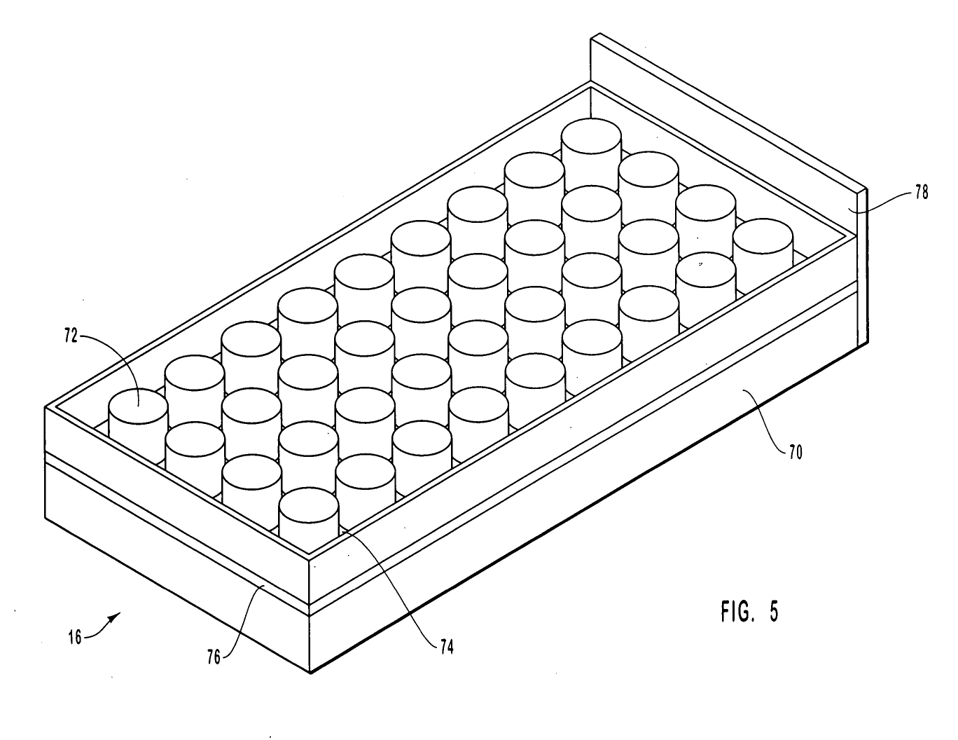

Depicted in FIG. 5 is an exemplary configuration of detector assembly 16. A housing 70 of detector assembly 16 supports one or more optical detectors 72. These optical detectors are positioning in the same spatial relationship as holders 46 of burn-in rack 14. So that when detector assembly 16 and burn-in rack 14 mount within support structure 12, laser diodes 34 (FIG. 4) disposed in holders 46 are generally aligned with a respective ones of optical detectors 72. The optical detectors are preferably calibrated optical detectors. Each optical detector 72 is electrically coupled, such as by a signal bus 74 disposed upon a circuit board 76, to an electrical connector 78. The electrical connector 78 can be a circuit board with associated electrical components to enable electrical communication between computer 30 (FIG. 1) and detectors 72.

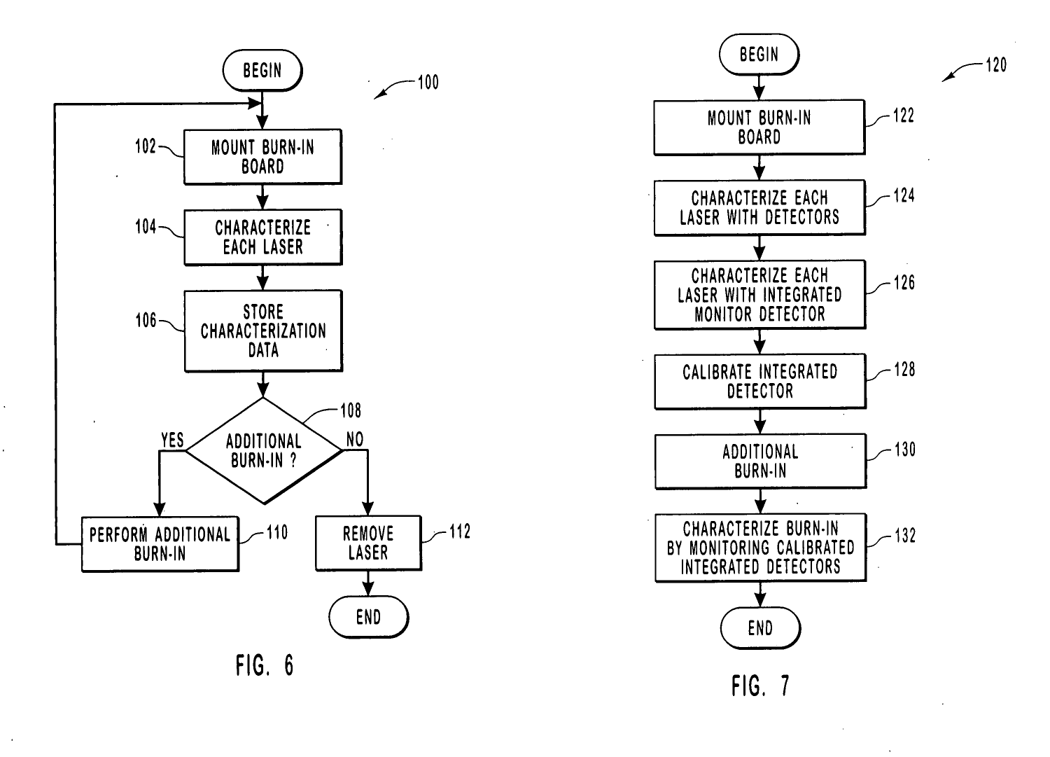

FIG. 6 illustrates one method of using system 10 to perform a burn-in process. In one embodiment, a method 100 includes mounting a burn-in board, having a plurality of laser diodes, to the support structure, as represented by block 102. Following mounting the burn-in board, each laser diode is characterized using the optical detectors of system 10 in combination with computer 30 (FIG. 1), as represented by block 104. This can include having the computer initiate pumping of electrical current through the laser diode and tracking the resultant power output from the laser diode using the detectors of the detector array. Additionally, this can include tracking other optical characteristics of the laser diode and the output electromagnetic radiation or wave. For instance, tracking or measuring optical power level, spatial beam characteristics, spectral beam characteristics, or other characteristics of the laser diode and/or the output therefrom. The detectors of the detector array can be used to achieve this characterizing process, however, other optical components or testing equipment can be used in tandem with the detectors. For instance, temperature controllers, thermally controlled mounts, optical-power measuring devices, optical power meters, or other equipment known to those skilled in the art. These devices and the detectors can be controlled by computer 30 (FIG. 1) based upon software integrated therein.

The characterization data generated from characterizing each laser diode is stored for later use, as represented by block 106. This can include storing the data in volatile or non-volatile memory of computer 30 (FIG. 1), whether or not such memory is fixably or removably associated with computer 30.

Using the characterization data, a decision is made whether the laser diodes on the burn-in board require additional burn-in at elevated temperature, as represented by decision block 108. This can include automatic determinations made by computer 30 (FIG. 1) based upon criterion stored in the memory. Alternatively, an operator of the system in combination with the computer can make the desired determination.

In the event that the laser diodes require more burn-in, as represented by decision block 108 being in the affirmative, the entire burn-in board is inserted into a burn-in oven for a preselected time and temperature, as represented by block 110. Following the additional burn-in process, the burn-in board is removed and remounted in system 10 where the laser diodes are tested again following the steps represented by blocks 102-108. The process can be cycled for a selected number of iterations until the laser diodes have been burned for the desired length of time. When the laser diodes require no additional burn-in processes, as represented by decision block 108 being negative, the laser diodes are removed from the burn-in board and can be used commercially, as represented by block 112.

FIG. 7 illustrates another method of using the system 10. In one embodiment, a method 120 includes mounting a burn-in board with laser diodes into the support structure of system 10, as represented by block 122. Following mounting the burn-in board, the laser diodes are characterized using the calibrated optical detectors of system 10, as represented by block 124. Each laser diode is also characterized using its own integrated monitor detector, as represented by block 126. Each integrated monitor detector is then calibrated using the characterization date from the calibrated optical detectors of system 10, as represented by block 128. This can, for example, include using measured power levels to determine the mathematical relationship between an output current at a fixed voltage of the monitor detectors and the actual output power levels. This calibration process is of general interest as characterization data for end users but can also be used in later life testing.

Following calibrating the laser diodes, the burn-in rack can then be removed and placed in a burn-in oven, as represented by block 130. The monitor detectors of each laser diode can then be used to characterize the laser diodes during further life testing, as represented by block 132. In some embodiments this permits, for example, further periodic testing of the laser diodes at room temperature using the monitor detectors. Additionally, useful information on laser degradation can also be acquired during elevated temperature testing using the calibrated monitor diodes.

One benefit of the present invention is that it reduces labor cost. Once laser diodes are mounted onto the holders of a burn-in rack they can be left in place throughout subsequent life testing. For example, with a laser burn-in rack with 50 laser diodes it can be desired to monitor the L-I degradation of the laser at periodic intervals, such as every 100 hours during an extended life test. Conventionally, during each test interval all of the laser diodes would have to be removed from the burn-in rack, individually tested, and returned to the burn-in rack. In the present invention, the laser diodes can be left on the burn-in rack and tested, reducing labor cost. Additionally, in embodiments in which the test apparatus is used to calibrate the monitor detectors of the lasers, the laser diodes can be characterized using the monitor detectors.

While particular embodiments and applications of the present invention have been illustrated and described, it is to be understood that the invention is not limited to the precise construction and components disclosed herein and that various modifications, changes and variations which will be apparent to those skilled in the art can be made in the arrangement, operation and details of the method and apparatus of the present invention disclosed herein without departing from the spirit and scope of the invention as defined in the appended claims.

What is claimed is:

1. A system for testing optoelectronic devices, the system comprising:
a burn-in rack mountable within a support structure, said burn-in rack supports a plurality of optoelectronic devices during burn-in testing and life testing, said burn-in rack with said plurality of optoelectronic devices being disposable in either a burn-in oven or within said support structure for life testing; and
a detector assembly mounted to said support structure, said detector assembly comprising a plurality of detectors, each of said plurality of detectors aligning with one of said plurality of optoelectronic devices to detect an output of each of said plurality of optoelectronic devices during the testing.

2. A system as recited in claim 1, wherein said system further comprising a computer in electrical communication with at least one of said burn-in rack and said detector assembly.

3. A system as recited in claim 2, wherein said computer controls said life testing and said burn-in testing.

4. A system as recited in claim 1, wherein said burn-in rack comprises:
a rack base that supports a circuit board; and
at least one diode support disposed from and supported by said rack base, said at least one diode support supporting said plurality of optoelectronic devices.

5. The system as recited in claim 1, wherein said plurality of detectors are organized in an array.

6. A system for life testing laser diodes, comprising:
a burn-in rack having a plurality of laser diode holders and electrical signal connectors for electrically coupling laser diodes mounted in said holders to a first electrical connector;
a test apparatus configured to hold said burn-in rack and having optical detectors arranged to receive light from said laser diodes mounted to said burn-in rack and couple output signals from said optical detectors to a second electrical connector;
a computer coupled to said first and second electrical connectors, said computer creating a drive current supplied to each laser diode and measuring the light output from said optical detectors.

7. A system as recited in claim 6, wherein said burn-in rack comprises:
a rack base that supports a circuit board; and
at least one diode support disposed from and supported by said rack base, said at least one diode support supporting said plurality of laser diode holders.

8. The system as recited in claim 6, wherein said plurality of detectors are organized in an array.

9. The system as recited in claim 6, wherein said electrical connectors are edge connectors.

10. The system as recited in claim 6, wherein said burn-in rack slidably cooperates with said test apparatus.

11. The system as recited in claim 6, wherein said burn-in rack is capable of being disposed within a burn-in oven.

12. A system for testing optoelectronic devices, the system comprising:
means for supporting a plurality of optoelectronic devices that are capable of undergoing a burn-in process;
means for detecting one or more operating characteristics of said plurality of optoelectronic devices; and
means, electrically coupled to said means for supporting and said means for detecting, for delivering a drive current to each of said plurality of optoelectronic devices and for measuring an output from said means for detecting.

13. The system as recited in claim 12, wherein said means for supporting comprises a burn-in rack.

14. The system as recited in claim 13, wherein said burn-in rack comprises a rack base and at least one diode support mounted to said rack base.

15. The system as recited in claim 14, wherein said burn-in rack further comprises at least circuit board electrically connected to a plurality of optoelectronic device holders and said plurality of optoelectronic devices disposed within said plurality of optoelectronic device holders.

16. The system as recited in claim 12, wherein said means for detecting comprises a detector assembly having a plurality of detectors.

17. The system as recited in claim 16, wherein said plurality of detectors detect electromagnetic waves propagated from said plurality of optoelectronic devices.

18. The system as recited in claim 12, wherein said means for detecting comprises a monitor detector integrated within each of said plurality of optoelectronic devices.

19. The system as recited in claim 12, wherein said means for delivering comprising a computer electrically connected to said plurality of optoelectronic devices and said means for detecting.

20. A method of testing laser diodes, comprising:
a step for mounting a burn-in rack having a plurality of optoelectronic devices to a test apparatus having an array of optical detectors;
a step for providing a drive current to each of said plurality of optoelectronic devices;
a step for measuring the optical power output of each optoelectronic device using said optical detectors; and
a step for storing optical characterization data for each of said plurality of optoelectronic devices.

21. The method as recited in claim 20, further comprising a step for characterizing each optoelectronic device based upon a monitor detector integrated with each optoelectronic device.

22. The method as recited in claim 20, further comprising a step for calibrating said integrated detector and said optical detectors.

23. The method as recited in claim 20, further comprising a step for removing said burn-in rack and performing a burn-in process.

24. The method as recited in claim 20, further comprising a step for removing each of said plurality of optoelectronic devices following an additional burn-in process.
